(19) United States
(12) Patent Application Publication
(10) Pub. No.: US 2024/0297366 A1
(43) Pub. Date: Sep. 5, 2024

(54) ENERGY STORAGE SYSTEM, COOLING SYSTEM, AND RELATED METHOD

(71) Applicant: Caterpillar Inc., Peoria, IL (US)

(72) Inventors: Umakanth SAKARAY, Dunlap, IL (US); Sean M. SCANLAN, Washington, IL (US); Kristina K. MELVIN, Rapid City, SD (US); Peyman ZAHEDI, Peoria, IL (US); Ming TIAN, Dunlap, IL (US)

(73) Assignee: Caterpillar Inc., Peoria, IL (US)

(21) Appl. No.: 18/177,285

(22) Filed: Mar. 2, 2023

(51) Int. Cl. H01M 10/6563; H01M 10/613; H01M 10/617; H01M 10/6556

(52) U.S. Cl. CPC H01M 10/6563; H01M 10/613; H01M 10/617; H01M 10/6556

(57) ABSTRACT

An energy storage system may include a container having a plurality of racks, a plurality of energy storage units supported on the racks, and an inverter cabinet containing an inverter, the inverter cabinet having an inverter cabinet inlet and an inverter exhaust duct. The energy storage system may also include an air temperature control unit configured to circulate conditioned air to the container via a supply duct and to receive returned air from the container via the inverter exhaust duct and a return duct, and at least one baffle, configured to receive the conditioned air from the air temperature control unit and to distribute the conditioned air to an interior of the container and to the inverter cabinet via the inverter cabinet inlet.

### TECHNICAL FIELD

The present disclosure relates generally to an energy storage system and a related cooling system and method, and, in particular, to an energy storage system having a cooling system for managing a thermal load of one or more energy sources and an inverter cabinet, located within a container, and a related method.

### BACKGROUND

Energy storage systems are used in commercial and industrial applications for peak shaving, load shifting, emergency backup, and various grid services. Energy storage systems include back-up energy sources (or primary energy sources), such as lithium ion batteries, used in various applications, such as remote constructions sites, remote medical facilities, or in vehicles. Energy storage systems may also include power electronics, such as an inverter. The energy sources and the power electronics are stored in a housing or a container, such as an industrial storage container, which may be provided with an air conditioning unit, to cool the components within the container and to prevent damage to those components due to humid ambient conditions. The energy sources and the power electronics generate and reject large amounts of heat during use, which may cause non-uniform heat distribution. In particular, heat generated by power electronics may be rejected into a space containing the energy sources, and may pass through the energy sources in order to reach a return duct of the air conditioning unit. Such rejected heat may cause non-uniform heat distribution among the energy sources, and the non-uniform heat distribution may lead to the non-uniform degradation of the energy sources. In addition, because the energy sources are connected to each other, in parallel and/or in series, a control and maintenance system for the energy sources may reduce a power output (also known as power derating) of the energy sources to reduce heat and prevent or minimize further degradation.

CN209418721U (“the '721 patent”) discusses a battery thermal management system comprising a box body, a battery bracket, an air conditioning unit, a battery module, an air supply duct, an air return duct, and a battery thermal management control cabinet. By means of a multi-air-vent design and matching of an air flow channel inside the battery module, cooling air output by the air conditioner can be uniformly sent to each battery module, and heated air can uniformly recovered. In particular, the battery bracket has an airwall provided with a plurality of air inlets and a plurality of air outlets, and the battery module is provided with a built-in fan. The multi-air-vent design of the '721 patent is relatively complex and specialized, in that it requires an airwall with the plurality of inlets and the plurality of outlets. Moreover, the battery thermal management system of the '721 patent does not contemplate or consider thermal management of other elements that may be housed within the box body.

The energy storage system, cooling system, and method of the present disclosure may solve one or more of the problems set forth above and/or other problems in the art. The scope of the current disclosure, however, is defined by the attached claims, and not by the ability to solve any specific problem.

### SUMMARY

In one aspect of the present disclosure, an energy storage system may include a container having a plurality of racks, a plurality of energy storage units supported on the racks, and an inverter cabinet containing an inverter, the inverter cabinet having an inverter cabinet inlet and an inverter exhaust duct. The system may also include an air temperature control unit configured to circulate conditioned air to the container via a supply duct and to receive returned air from the container via the inverter exhaust duct and a return duct, and at least one baffle, configured to receive the conditioned air from the air temperature control unit and to distribute the conditioned air to an interior of the container and to the inverter cabinet via the inverter cabinet inlet.

In another aspect of the present disclosure, a method of controlling a temperature of an energy storage system is provided. The energy storage system may include a container having a plurality of racks, a plurality of energy storage units supported on the racks, and an inverter cabinet containing an inverter, the inverter cabinet having an inverter cabinet inlet and an inverter exhaust duct. The energy storage system may also include an air temperature control unit configured to circulate conditioned air to the container via a supply duct and to return air from the container via the inverter exhaust duct and a return duct, and at least one baffle, configured to receive the conditioned air from the air temperature control unit and to distribute the conditioned air to an interior of the container and to the inverter cabinet via the inverter cabinet inlet. The method may include supplying the conditioned air from the air temperature control unit to the container via the supply duct and the at least one baffle, circulating air through the inverter cabinet via the inverter cabinet inlet, returning air that has passed through the inverter cabinet to the container via the inverter exhaust duct, and returning air that has passed through the plurality of energy storage units and through the inverter cabinet to the air temperature control unit via the return duct.

In still another aspect of the present disclosure, a cooling system for an energy storage system is provided. The energy storage system may include a container having a plurality of racks, a plurality of energy storage units supported on the racks, and an inverter cabinet containing an inverter, the inverter cabinet having an inverter cabinet inlet and an inverter exhaust duct. The cooling system may include an air temperature control unit configured to generate conditioned air, a supply duct configured to output the conditioned air generated by the air temperature control unit to the container, the inverter cabinet inlet configured to draw in air to the inverter cabinet, at least one baffle for reducing a flow of air, the at least one baffle being configured to receive the conditioned air from the air temperature control unit and to distribute the conditioned air to an interior of the container and to the inverter cabinet via the inverter cabinet inlet, the inverter exhaust duct configured to output air from the inverter cabinet in a direction towards the at least one baffle, and a return duct configured to draw in air having passed through the one or more energy storage units, and output by the inverter exhaust duct, and return the air to the air temperature control unit.

### BRIEF DESCRIPTION OF THE DRAWINGS

FIG. 1 shows a view of an energy storage system, including a container that stores an energy source and an inverter cabinet, as well as an air temperature control unit, in accordance with the present disclosure.

FIG. 2 shows another view of the energy storage system shown in FIG. 1, including a supply duct and a return duct of a cooling system, in accordance with the present disclosure.

FIG. 3 shows still another view of the energy storage system shown in FIG. 1, including a schematic view of thermal management within the energy storage system.

FIG. 4 shows a schematic view of a horizontal baffle and vertical baffles of the energy storage system shown in FIGS. 1 to 3.

FIG. 5 shows a detail view of perforations which may be provided on the horizontal baffle and the vertical baffles shown in FIG. 4.

FIG. 6 shows a schematic view of an inverter exhaust duct of the energy storage system shown in FIGS. 1 to 3.

FIG. 7 shows a top view of the inverter exhaust duct of the energy storage systems shown in FIGS. 1 to 3.

FIG. 8 shows a flowchart of a method of providing thermal management for an energy storage system, in accordance with the present disclosure.

### DETAILED DESCRIPTION

Both the foregoing general description and the following detailed description are exemplary and explanatory only and are not restrictive of the features, as claimed. As used herein, the terms “comprises,” “comprising,” “having,” including,” or other variations thereof, are intended to cover a non-exclusive inclusion, such that a process, method, article, or apparatus that comprises a list of elements does not include only those elements, but may include other elements not expressly listed or inherent to such a process, method, article, or apparatus. In addition, in this disclosure, relative terms, such as, for example, “about,” “generally, “substantially,” and “approximately” are used to indicate a possible variation of ±10% in the stated value.

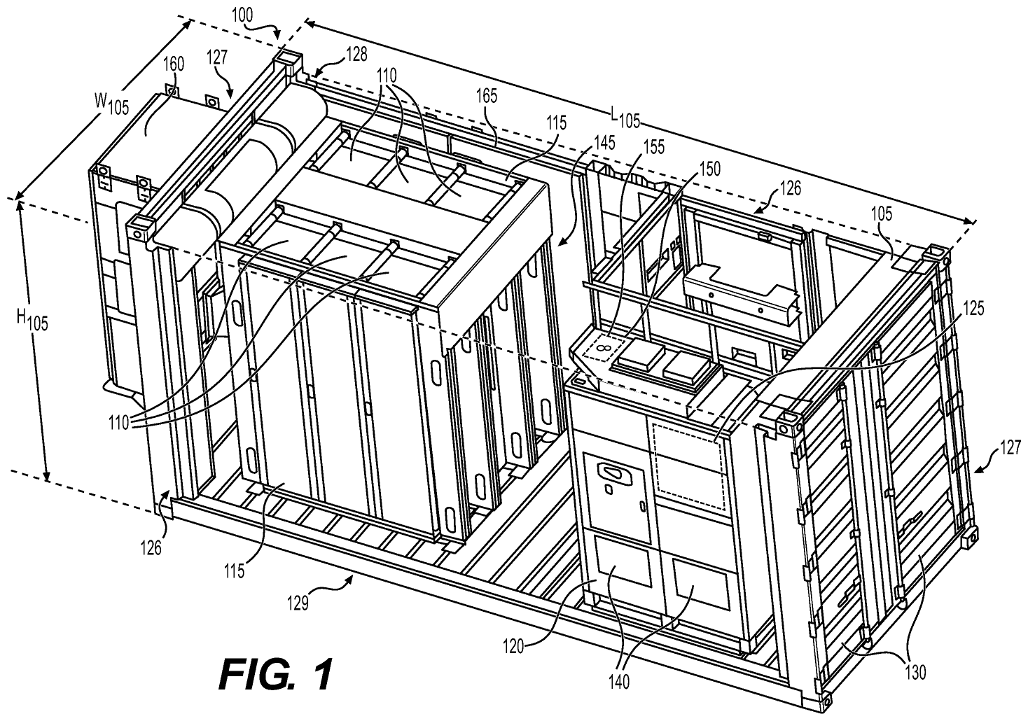

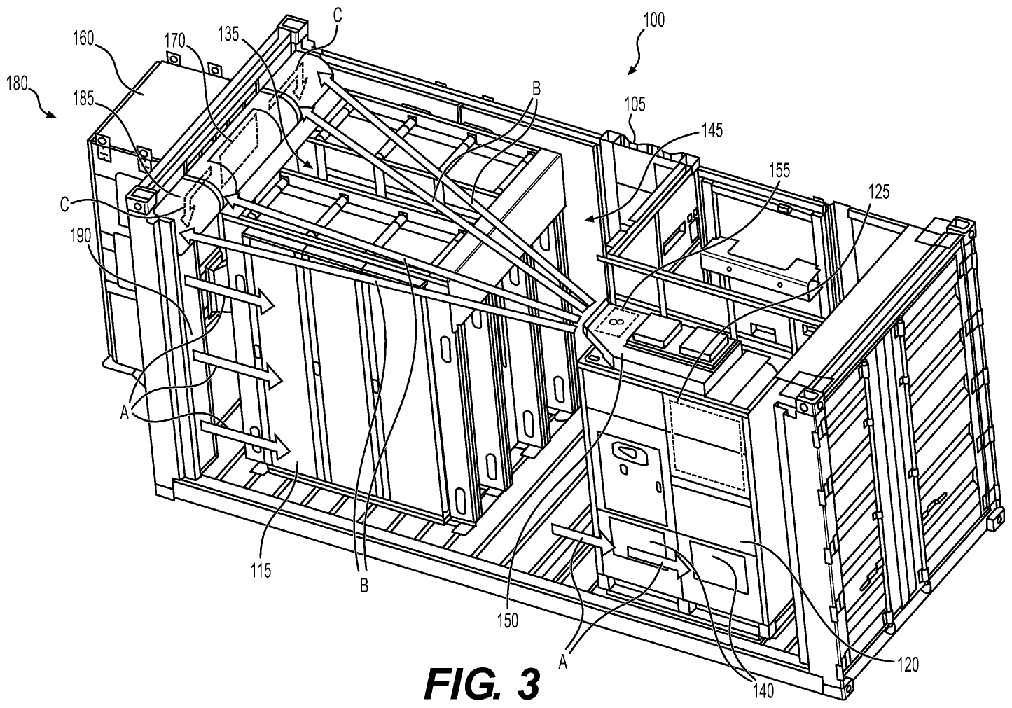

FIG. 1 shows a view of an energy storage system 100 of the present disclosure. The energy storage system 100 includes an energy storage container 105 (hereinafter, container) that houses one or more energy sources 110 (or energy storage units) on one or more racks 115, and an inverter cabinet 120 which houses an inverter 125. The container 105 may be an intermodal container, also known as a shipping container or a storage container, of a standard ISO (International Organization for Standardization) size, having a length L₁₀₅ of about 20 feet (5.9 m) or about 40 feet (12.03 m), a width W₁₀₅ of about 8 feet (2.44 m), and a height H₁₀₅ of about 8.5 feet (2.59 m) or about 9.5 feet (2.9 m). The container 105 may have six surfaces, namely, two side surfaces 126, two end surfaces 127, an upper surface or roof 128, and a lower surface or bottom 129. The container 105 may have one or more doors 130 at one end thereof. The racks 115 and the energy sources 110 are arranged in a center-aisle configuration, such that a center aisle 135 (shown in FIG. 3) is formed between two sets of racks 115. The inverter cabinet 120 has one or more inverter cabinet inlets 140 (in this embodiment, two inlets 140 are shown), through which air from an interior 145 of the storage container 105 is drawn into the inverter cabinet 120. The inverter cabinet 120 also has an inverter exhaust duct 150 located on top of the inverter cabinet 120. The location of the inverter exhaust duct 150 is not, however, limited to a top of the inverter cabinet 120, and the inverter exhaust duct 150 may be provided at other locations. The inverter exhaust duct 150 houses an inverter cabinet fan 155 which draws air from within the inverter cabinet 120 into the inverter exhaust duct 150, and rejects or outputs that air into the interior 145 of the storage container 105, as discussed in more detail below with respect to FIGS. 3 and 8.

The energy sources 110 may be batteries, such as lithium ion batteries having chemistries including lithium cobalt oxide (LCO), lithium nickel cobalt aluminum oxide (NCA), lithium nickel manganese cobalt oxide (NMC), and lithium iron phosphate (LFP), lead acid batteries, flow batteries, sodium nickel chloride batteries, and lithium iron batteries, stored in one or more racks 115 within the storage container 105. For example, the energy sources 110 may be stored in four racks 115 or six racks 115. Each energy source 110 may be part of a module (e.g., a battery module) that has a fan (not shown), which draws air around the energy source 110, so that the air absorbs heat from the energy source 110 and thereby cools the energy source 110.

The energy storage system 100 also includes an air temperature control unit 160, such as a heating, ventilation, and air conditioning (HVAC) unit, attached to the storage container 105 at an end opposite the doors 130. The air temperature control unit 160 may be end mounted, as shown in FIG. 1, although other arrangements of the air temperature control unit 160 may be used. As discussed in more detail below, the air temperature control unit 160 provides thermal management to the energy storage system 100, specifically by providing conditioned air to the interior 145 of the storage container 105 and to the inverter cabinet 120. Walls 165 of the storage container 105 may be insulated to further manage temperature of components housed within the storage container 105.

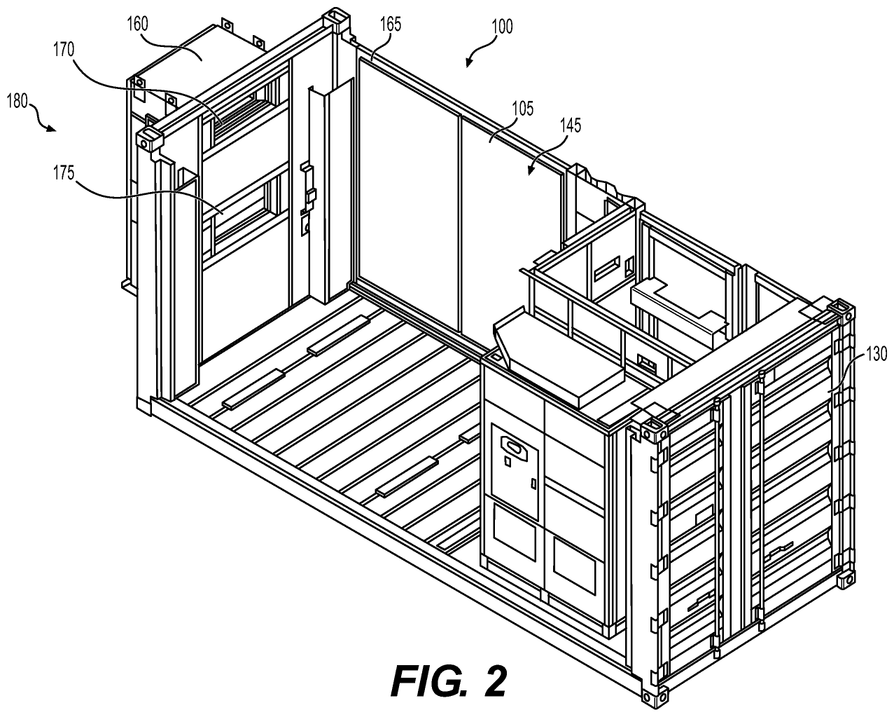

FIG. 2 shows another view of the energy storage system 100 shown in FIG. 1, including a supply duct 170 and a return duct 175 of a cooling system 180. That is, FIG. 2 shows the energy storage system 100 of FIG. 1, with the racks 115 and energy sources 110 removed, so that the supply duct 170 and the return duct 175 of the cooling system 180 are visible. The supply duct 170 and the return duct 175 are located within the walls 165 of the storage container 105, and are fluidly connected to the air temperature control unit 160, so that conditioned air from the air temperature control unit 160 is configured to flow to the interior 145 of the storage container 105 via the supply duct 170, and air that has cooled (or absorbed heat from) the energy sources 110 and/or the inverter cabinet 120 is configured to flow to the air temperature control unit 160 via the return duct 175. In this embodiment, the supply duct 170 and the return duct 175 are at an end of the storage container 105 opposite to an end with the doors 130.

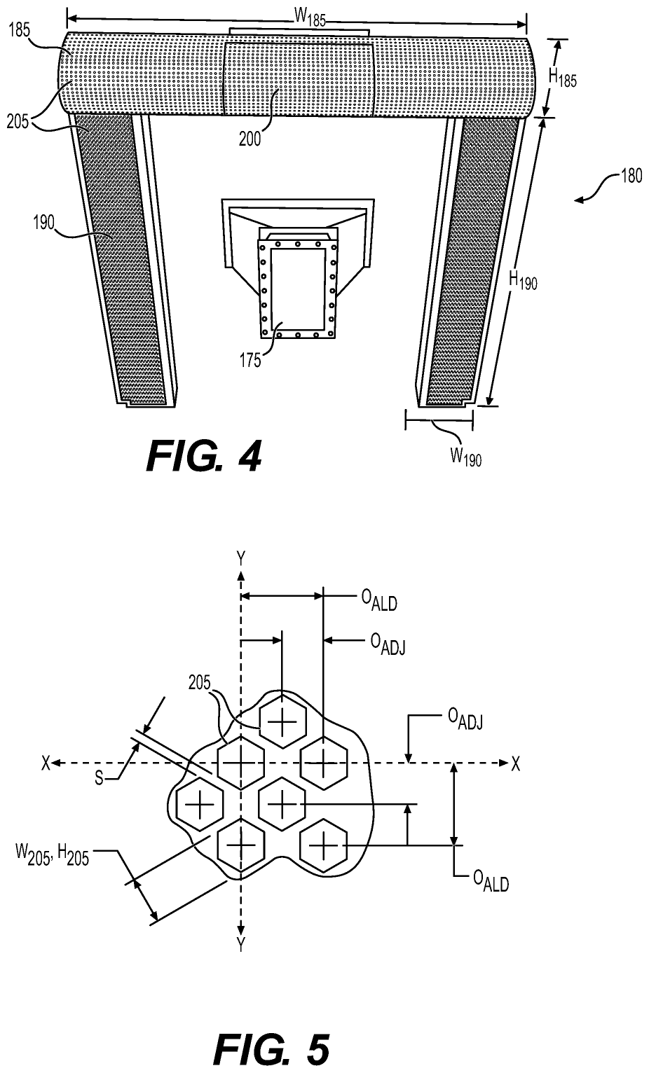

FIG. 3 shows another view of the energy storage system 100 shown in FIGS. 1 and 2, including a schematic view of portions of the cooling system 180 for the energy storage system 100. The cooling system 180 may include the air temperature control unit 160, the supply duct 170, the inverter cabinet inlets 140, the inverter exhaust duct 150, and the return duct 175. The cooling system 180 may further include a horizontal baffle 185 and one or more vertical baffles 190, shown in FIGS. 3 and 4. In particular, FIG. 3 shows supply of conditioned air A from the air temperature control unit 160 to the interior 145 of the storage container 105 via at least one vertical baffle 190 that extends down alongside the racks 115. A second vertical baffle 190 may extend along another side of the interior 145 of the storage container 105, and is shown in FIG. 4. Dashed arrows C, shown in FIG. 3, show a direction of conditioned air within the horizontal baffle 185, from the supply duct 170 to the vertical baffles 190 that extend along the sides of the interior 145 of the storage container 105. At least a portion of the conditioned air A flows around and through the racks 115 to cool the energy sources 110 stored on the racks 115, and at least another portion of the conditioned air A flows to the inverter cabinet 120. The conditioned air A that flows through the racks 115 cools, or absorbs heat from, the energy sources 110, that is, the air becomes heated air B, and the heated B air flows to the center aisle 135, and then back to the air temperature control unit 160 via the return duct 175, shown in FIG. 2.

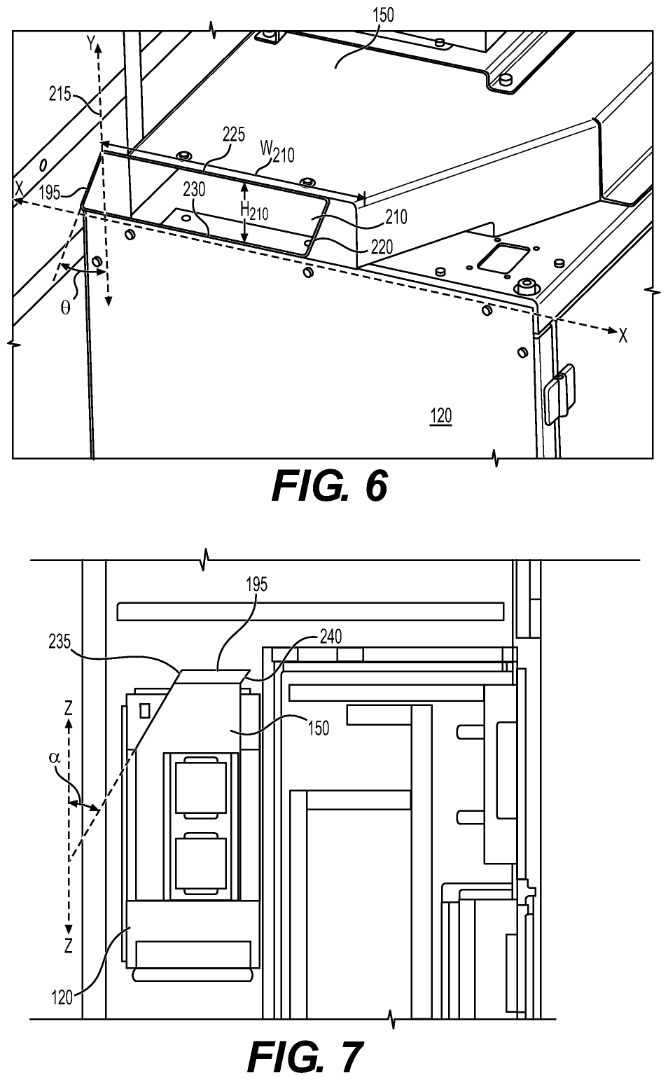

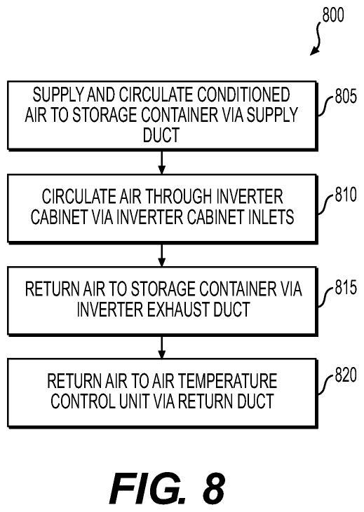

The portion of the conditioned air A that flows to the inverter cabinet 120 may be drawn into the inverter cabinet 120 by the inverter cabinet fan 155 and/or one or more additional fans (not shown) of the inverter cabinet 120, via the inverter cabinet inlets 140. The conditioned air A cools, or absorbs heat from, the inverter 125, that is, the conditioned air becomes heated air B, and the heated air B then flows upward through the inverter exhaust duct 150, and is output or rejected from the inverter exhaust duct 150 via an inverter exhaust outlet 195 (FIGS. 6 and 7). The fan(s) of the inverter cabinet 120, such as inverter cabinet fan 155, may create suction within the inverter cabinet 120 to draw the heated air B upward through the inverter exhaust duct 150. Then, the heated air B output from the inverter exhaust duct 150 flows into the horizontal baffle 185 and mixes with conditioned air A from the supply duct 170, as discussed in more detail below with reference to FIG. 4.

FIG. 4 shows the horizontal baffle 185, two vertical baffles 190, and the return duct 175 of the cooling system 180. The horizontal baffle 185 extends horizontally, and includes an area 200 in which heated air exhausted by the inverter exhaust duct 150 mixes with conditioned air from the supply duct 170. In addition, the horizontal baffle 185 is rounded, or bulges, towards the interior 145 of the storage container 105 (as can also be seen in FIGS. 1 and 3). More specifically, the horizontal baffle 185 bulges toward an opposite end of the storage container 105, that is, the end on which the doors 130 may be provided. The mixing of the heated air from the inverter cabinet 120 with the conditioned air from the supply duct 170 minimizes variation in temperatures of the energy sources 110. The vertical baffles 190 extend from ends of the horizontal baffle 185, as shown in FIG. 4, and conditioned air is supplied from the horizontal baffle 185 to the vertical baffles 190 to the interior 145 of the storage container 105. The horizontal baffle 185 ensures an approximately equal split of the conditioned air to both sides, or banks, of the racks 115. The return duct 175 is located within a wall 165 of the storage container 105, below the horizontal baffle 185 and in between the two vertical baffles 190.

FIG. 4 also shows a plurality of perforations 205 provided on both the horizontal baffle 185 and the vertical baffles 190. The perforations 205 are provided along substantially an entire width W₁₈₅ and an entire height H₁₈₅ of the horizontal baffle 185, and along substantially an entire width W₁₉₀ and an entire height H₁₉₀ of the vertical baffles 190. However, the perforations 205 may be provided only on portions of the horizontal baffle 185 and/or the vertical baffles 190. For example, perforations 205 may be provided only on bottom portions (i.e., the bottom half) of each vertical baffle 190. The perforations 205 collectively act as a diffuser to spread the conditioned air from the horizontal baffle 185 and the vertical baffles 190 towards the energy sources 110. That is, the perforations 205 ensure uniform delivery of conditioned air to each rack 115 and to each energy source 110 stored within each rack 115. In addition, the perforated horizontal baffle 185 and vertical baffles 190 slow air (that is, the perforations 205 reduce a velocity of air) flowing from the supply duct 170 to the interior 145 of the storage container 105, which ensures better mixing of the conditioned air and the heated air from the inverter cabinet 120.

FIG. 5 is a detail view of the perforations 205 that may be provided on the horizontal baffle 185 and the vertical baffles 190. In particular, the perforations 205 may have one or more of a particular shape, spacing, pattern or arrangement, and/or size. In one embodiment, the perforations 205 may have a hexagonal shape, as shown in FIG. 5. The perforations 205 may, however, have others shapes, including circular, oval, ovoid, square, rectangular, trapezoidal, or other geometric shapes, and may be distributed as described below. The perforations 205 may also be in the form of slots or other types of openings. The perforations 205 may be formed in the horizontal baffle 185 and the vertical baffles 190 by stamping, although other manufacturing methods may be used.

The perforations 205 may be arranged in an offset pattern, in which centers of alternating perforations 205 are aligned along a vertical axis Y-Y and/or a horizontal axis X-X, with one intervening offset perforation 205, and perforations 205 in immediately adjacent columns are staggered, as shown in FIG. 5. An offset distance O_{ADJ} between centers of immediately adjacent perforations 205 in the offset pattern may be in a range of about 5 mm to about 20 mm, about 9 mm to about 15 mm, and, more specifically, for example, about 9.9±0.15 mm. An offset distance O_{ALD} between centers of aligned perforations 205 may be in a range of about 10 mm to about 40 mm, about 15 mm to about 25 mm, and, more specifically, about 19.8±0.15 mm. However, other patterns and arrangements and varying offset distances may be used. For example, centers of all of the perforations 205 may be aligned.

A spacing S between edges of adjacent perforations 205 may be within a predetermined range, for example, within a range of 1 mm to 3 mm, and, more particularly, may be 2 mm. However, the spacing S may be greater than 3 mm or less than 1 mm, for example, within a range of about 1 mm to about 6 mm. Each perforation 205 may have a width W₂₀₅ and a height H₂₀₅ that are within predetermined ranges of values. For example, a width W₂₀₅ of each of the hexagonal perforations 205 may be within a range of 5.0 to 20.0 mm, and, more particularly, may be 11.5 mm. A ratio of total perforation area to total surface area of one of the horizontal baffle 185 or one of the vertical baffles 190 may be within a predetermined range. For example, the predetermined range of ratios may be from 0.3:1.0 to 0.8:1.0, or, more particularly, 0.6:1.0.

FIG. 6 shows the inverter exhaust duct 150, and in particular, shows the inverter exhaust outlet 195 with an opening 210. The opening 210 includes two opposing side surfaces 215, 220, a top surface 225, and a bottom surface 230. The opening 210, and in particular, the surfaces 215, 220, 225, and 230 define a throw area of the inverter exhaust duct 150 that determines the direction in which conditioned air is thrown. In a case in which the opening 210 is a rectangular opening, the throw area may be defined as a product of a height H₂₁₀ of the opening 210 and a width W₂₁₀ of the opening 210. The throw area may be optimized to facilitate better mixing of the heated air from the inverter cabinet 120 with conditioned air from the supply duct 170. As another measure of the ability of the inverter exhaust duct 150 to facilitate mixing of heated air and conditioned air, the opening 210 may have an air throw value, or simply, throw, which may be expressed as a velocity measurement, specifically, an air terminal velocity, and which indicates how well the air shifts from the inverter exhaust duct 150 to the interior 145 of the storage container.

With reference to FIG. 6, each of opposing side surfaces 215, 220 of the opening 210 may be at an angle θ relative to a vertical axis Y-Y, as shown, while the top surface 225 and the bottom surface 230 may be parallel to each other and to a horizontal axis X-X. The angle θ may be within a range of about 15° to about 25°, and, more particularly, may be about 21°. The width W₂₁₀ of the opening 210, which is a distance between the opposing side surfaces, may be within a range of about 340 mm to about 360 mm, and, more particularly, may be about 349 mm, and the height H₂₁₀ of the opening 210, which is a distance between the top surface and the bottom surface, may be within a range of about 80 mm to about 100 mm, and, more particularly, may be about 93 mm. Further, a ratio of the height H₂₁₀ of the opening 210 and the width W₂₁₀ of the opening may be within a range of 0.2 to 0.3.

FIG. 7 shows a top view of the energy storage system 100, and, in particular, shows another angle α formed by side portions 235, 240 of the inverter exhaust outlet 195. That is, the side portions 235, 240 of the inverter exhaust outlet 195 extend in a direction that is at angle α relative to a horizontal axis Z-Z, as shown. The angle α may be within a range of about 20° to about 40°, and, more particularly, may be 30°. By virtue of the angle θ between the side surfaces 215, 220 of the opening 210 of the inverter exhaust outlet 195 and a vertical axis Y-Y, and the angle α between the side portions 235, 240 of the inverter exhaust outlet 195 and a horizontal axis Z-Z, heated air output by the inverter exhaust outlet 195 is directed towards the horizontal baffle 185, and, in particular, the area 200 of the horizontal baffle 185 in which the heated air mixes with conditioned air from the supply duct 170. Put another way, the throw area of the inverter exhaust duct 150 may be aligned with the area 200 of the horizontal baffle 185 in which the heated air from the inverter cabinet 120 is mixed with conditioned air from the supply duct 170. Directing the heated air towards the area 200 of the horizontal baffle 185 improves exhaust mixing, that is, mixing of the heated air with supply air, and reduces a velocity gradient of conditioned air at the horizontal baffle 185 and the vertical baffles 190.

### INDUSTRIAL APPLICABILITY

The energy storage system 100, including the cooling system 180, and the related method 800, described below, may be used for an energy storage container 105 that is a mobile system or a stationary system, on grid or off grid, and in various environments and ambient temperatures. In addition, by virtue of the overall size of the energy storage system 100, the system 100 may be transported, such as on a bed of a truck.

FIG. 8 shows a flowchart of a method 800 of providing thermal management for an energy storage system 100, in accordance with the present disclosure. The method 800 may include a step 805 of supplying conditioned air from the air temperature control unit 160 to the storage container 105 via the supply duct 170. The method 800 may also include a step 810 of circulating air through the inverter cabinet 120 via the one or more inverter cabinet inlets 140. In addition, the method 800 may include a step 815 of returning air that has passed through the inverter cabinet 120 to the storage container 105 via the inverter exhaust duct 150. The method 800 may include a step 820 of returning air that has passed through the one or more energy sources 110 and through the inverter cabinet 120 to the air temperature control unit 160 via the return duct 175.

The energy storage system 100, the cooling system 180, and the related method 800 provide for efficient cooling of an energy storage container 105, and, in particular, of energy sources 110 and an inverter 125 within an inverter cabinet 120, to minimize variations in velocity and temperature of air that flows among these elements and to avoid a reduction of power output which may occur when a temperature of one of the energy sources 110 is relatively high as a result of a non-uniform heat distribution. In particular, by virtue of the cooling system 180 that provides conditioned air to the storage container 105 via the horizontal baffle 185 and the vertical baffles 190 with perforations 205, the energy sources 110 on the racks 115 within the storage container 105 may be uniformly cooled to maintain temperature variations among the energy sources 110 within a relatively small range. In particular, the perforations 205 provided in the horizontal and vertical baffles 190 of the cooling system 180 ensure uniform delivery of conditioned air, in terms of both velocity and temperature, to each rack 115 and to each energy source 110 stored within each rack 115, resulting in the same or substantially the same rate of degradation of all energy sources 110, rather than one energy source 110 or few energy sources 110 experiencing heavy degradation and affecting the energy output of the entire rack 115 of energy sources 110.

Further, by virtue of the inverter cabinet fan 155, conditioned air from within the storage container 105 may be drawn into the inverter cabinet 120 and output, or rejected, by the inverter exhaust duct 150, providing for thermal management of the inverter 125 within the inverter cabinet 120. Still further, by virtue of the opening 210 of the inverter exhaust duct 150 and the relative dimensions and angles of the various surfaces of the opening 210, heated air from the inverter cabinet 120 may be directed to the horizontal baffle 185, where it can be mixed with conditioned air, so as to minimize any non-uniform heating effect of the heated air from the inverter cabinet 120 on the energy sources 110. And, by virtue of the uniform mixing and delivery of the conditioned air, all energy sources 110 may experience degradation at the same or substantially the same rate, rather than one energy source 110 or few energy sources 110 experiencing heavy degradation and affecting the energy output of the entire rack 115 of energy sources 110. The energy storage system 100, and in particular, the cooling system 180, provide for efficient thermal management not only of energy sources 110, but of other components within the storage container 105, e.g., an inverter 125, while accounting for the flow and the effect of heated air resulting from cooling such other components. In addition, the cooling system 180 does not require specialized equipment having multiple inlets and multiple outlets, which may limit an arrangement of energy sources 110 stored within such an energy storage system 100. In other words, the energy storage system 100, the cooling system 180, and the related method of the present disclosure provide for thermal management of energy sources 110 of varying configurations, as well as thermal management of other components within a storage container 105, while minimizing non-uniform temperature distributions among the energy sources 110. Also, by virtue of providing such a system 100 with a container 105 that is an intermodal container of a standard ISO (International Organization for Standardization) size, the system 100 can be easily transported to sites, including remote mining sites, and via multiple modes of transportation, i.e., by road, rail, or sea.

It will be apparent to those skilled in the art that various modifications and variations can be made to the disclosed energy storage system 100, the cooling system 180, and the related method 800, without departing from the scope of the disclosure. Other embodiments of the energy storage system 100, the cooling system 180, and the related method 800 will be apparent to those skilled in the art from consideration of the specification and the accompanying figures. It is intended that the specification, and, in particular, the examples provided herein be considered as exemplary only, with a true scope of the disclosure being indicated by the following claims and their equivalents.

We claim:

1. An energy storage system comprising:
a container having:
a plurality of racks;
a plurality of energy storage units supported on the racks; and
an inverter cabinet containing an inverter, the inverter cabinet having an inverter cabinet inlet and an inverter exhaust duct;
an air temperature control unit configured to circulate conditioned air to the container via a supply duct and to receive returned air from the container via the inverter exhaust duct and a return duct; and
at least one baffle, configured to receive the conditioned air from the air temperature control unit and to distribute the conditioned air to an interior of the container and to the inverter cabinet via the inverter cabinet inlet.

2. The energy storage system of claim 1, wherein the at least one baffle comprises at least one horizontal baffle and at least one vertical baffle, and the conditioned air is circulated to the container via the at least one horizontal baffle and the at least one vertical baffle.

3. The energy storage system of claim 2, wherein each of the at least one horizontal baffle and the at least one vertical baffle includes a plurality of perforations.

4. The energy storage system of claim 3, wherein the plurality of perforations are provided on at least a lower portion of the at least one vertical baffle.

5. The energy storage system of claim 1, wherein the inverter exhaust duct has an opening that is angled upwards, relative to a horizontal axis, to direct returned air towards at least one baffle.

6. The energy storage system of claim 1, wherein the inverter exhaust duct has an opening that is angled relative to a vertical axis, to direct returned air towards the at least one baffle.

7. The energy storage system of claim 1, wherein the inverter exhaust duct has an opening with a throw area having a width of at least 340 mm and a height of at least 80 mm.

8. A method of controlling a temperature of an energy storage system, the energy storage system comprising:
a container having:
a plurality of racks;
a plurality of energy storage units supported on the racks; and
an inverter cabinet containing an inverter, the inverter cabinet having an inverter cabinet inlet and an inverter exhaust duct;
an air temperature control unit configured to circulate conditioned air to the container via a supply duct and to return air from the container via the inverter exhaust duct and a return duct; and
at least one baffle, configured to receive the conditioned air from the air temperature control unit and to distribute the conditioned air to an interior of the container and to the inverter cabinet via the inverter cabinet inlet,
the method comprising:
supplying the conditioned air from the air temperature control unit to the container via the supply duct and the at least one baffle;
circulating air through the inverter cabinet via the inverter cabinet inlet;
returning air that has passed through the inverter cabinet to the container via the inverter exhaust duct; and
returning air that has passed through the plurality of energy storage units and through the inverter cabinet to the air temperature control unit via the return duct.

9. The method of claim 8, wherein the at least one baffle comprises at least one horizontal baffle and at least one vertical baffle, and the conditioned air is circulated to the container via the at least one horizontal baffle and the at least one vertical baffle.

10. The method of claim 9, wherein each of the at least one horizontal baffle and the at least one vertical baffle includes a plurality of perforations.

11. The method of claim 10, wherein the plurality of perforations are provided on at least a lower portion of the at least one vertical baffle.

12. The method of claim 8, wherein the inverter exhaust duct has an opening that is angled upwards, relative to a horizontal axis, to direct returned air towards the at least one baffle.

13. The method of claim 8, wherein the inverter exhaust duct has an opening that is angled relative to a vertical axis, to direct returned air towards the at least one baffle.

14. The method of claim 8, wherein the inverter exhaust duct has an opening with a throw area having a width of at least 340 mm and a height of at least 80 mm.

15. A cooling system for an energy storage system, the energy storage system having:
a container having:
a plurality of racks;
a plurality of energy storage units supported on the racks; and
an inverter cabinet containing an inverter, the inverter cabinet having an inverter cabinet inlet and an inverter exhaust duct; and
the cooling system comprising:
an air temperature control unit configured to generate conditioned air;
a supply duct configured to output the conditioned air generated by the air temperature control unit to the container;
the inverter cabinet inlet configured to draw in air to the inverter cabinet;
at least one baffle for reducing a flow of air, the at least one baffle being configured to receive the conditioned air from the air temperature control unit and to distribute the conditioned air to an interior of the container and to the inverter cabinet via the inverter cabinet inlet;
the inverter exhaust duct configured to output air from the inverter cabinet in a direction towards the at least one baffle; and
a return duct configured to draw in air having passed through the one or more energy storage units, and output by the inverter exhaust duct, and return the air to the air temperature control unit.

16. The cooling system of claim 15, wherein the at least one baffle comprises at least one horizontal baffle and at least one vertical baffle, and the conditioned air is circulated to the container via the at least one horizontal baffle and the at least one vertical baffle.

17. The cooling system of claim 16, wherein each of the at least one horizontal baffle and the at least one vertical baffle includes a plurality of perforations.

18. The cooling system of claim 17, wherein the plurality of perforations are provided on at least a lower portion of the at least one vertical baffle.

19. The cooling system of claim 15, wherein the inverter exhaust duct has an opening that is angled upwards, relative to a horizontal axis, to direct returned air towards the at least one baffle.

20. The cooling system of claim 15, wherein the inverter exhaust duct has an opening with a throw area having a width of at least 340 mm and a height of at least 80 mm.
